(19) United States
(12) Patent Application Publication
(10) Pub. No.: US 2026/0047215 A1
(43) Pub. Date: Feb. 12, 2026

(54) SEMICONDUCTOR LIGHT-RECEIVING DEVICE AND METHOD FOR MANUFACTURING SAME

(71) Applicant: Mitsubishi Electric Corporation, Tokyo (JP)

(72) Inventors: Harunaka YAMAGUCHI, Tokyo (JP); Yasunori MIYAZAKI, Tokyo (JP)

(73) Assignee: Mitsubishi Electric Corporation, Tokyo (JP)

(21) Appl. No.: 19/150,069

(22) PCT Filed: Apr. 11, 2023
(86) PCT No.: PCT/JP2023/014682

§ 371 Date: Jul. 22, 2025

(51) Int. Cl. H10F 30/225; H10F 77/124

(52) U.S. Cl. CPC H10F 30/2255; H10F 77/1248

(57) ABSTRACT

A semiconductor light-receiving device (100) according to the present disclosure includes: a semiconductor substrate (2); a digital alloy-type multiplication layer (4) formed above the semiconductor substrate (2) and having a digital alloy structure comprising alternately stacked multiple layers of a plurality of first semiconductor layers comprising a superlattice layer made of IV group atoms and a plurality of second semiconductor layers having a bandgap energy larger than a bandgap energy of the first semiconductor layer; an electric field control layer (5) formed above the digital alloy-type multiplication layer (4) and configured to relax an electric field; and a light absorption layer (6) formed above the electric field control layer (5) and configured to absorb incident light.

### TECHNICAL FIELD

The present disclosure relates to a semiconductor light-receiving device and a method for manufacturing the same.

### BACKGROUND ART

In recent years, the data center market has made remarkable progress due to the spread of business that handle large amounts of data and video content. Accordingly, demand for optical communication devices necessary for high-capacity data communication is increasing. Avalanche photodiodes (APDs) with excellent performance are essential as optical communication devices on the receiving side of communication data not only in short-distance communication but also in long-distance communication between data centers.

APDs used on the receiving side generate photocarriers consisting of electron-hole pairs from optical signals received during data communication, and can amplify the photocarriers themselves. Consequently, using APDs makes it possible to restore accurate optical signals on the receiving side even in long-distance transmission where signal intensity deteriorates. Furthermore, using APDs makes it possible to downsize communication devices because the external carrier amplifiers on the receiving side that are necessary when using ordinary light-receiving devices are no longer needed. For this reason, APDs are used as semiconductor light-receiving devices even in short-distance communication.

The main device structure of APDs used in current optical communications is a SACM-type APD structure (Separate Absorption, Charge and Multiplication Avalanche Photodiode) in which a layer for generating photocarriers by receiving signal light and a layer for multiplying the generated photocarriers are separated. In particular, the SACM-type APD structure, which comprises an InGaAs absorption layer to receive signal light and generate the photocarriers, an AlInAs multiplication layer to multiply the generated carriers, and an electric field control layer to control the electric field intensity of the multiplication layer such that the photocarriers can be avalanche multiplied, which are formed above an InP substrate, is used. The photocarriers generated in the InGaAs absorption layer are conducted into the AlInAs multiplication layer by reverse biasing, and then the photocarriers are avalanche amplified in the multiplication layer, making it possible to amplify optical signals (Patent Document 1).

With the increase in the speed of communication, APDs with lower noise operation than the current APDs are required. In order to reduce the noise of APDs, it is necessary to reduce the hole noise generated in the multiplication layer. For this purpose, APDs in which the hole noise during multiplication is suppressed using germanium (Ge) absorption layer and Si multiplication layer formed on silicon (Si) substrate have started to be used in recent years (Non-Patent Document 1).

### CITATION LIST

### Patent Document

Patent Document 1: Japanese Patent No. 4166560
Patent Document 2: Japanese Laid-Open Patent Publication No. 61-276272
Patent Document 3: Japanese Patent No. 2730472

### Non-Patent Document

Non-Patent Document 1: M. Huang, et al., “Germanium on Silicon Avalanche Photodiode”, IEEE Journal of Selected Topics In Quantum Electronics, Vol. 24, No. 2, 3800911, 2018
Non-Patent Document 2: M. Daoudi, et al., “Si-delta doping and spacer thickness effects on the electronic properties in Si-delta-doped AlGaAs/GaAs HEMT structures”, Superlattices and Microstructures, Vol. 51, pp. 497-505, 2012
Non-Patent Document 3: J. Zheng, et al., “Digital Alloy InAlAs Avalanche Photodiodes”, IEEE Journal of Lightwave Technology, Vol. 36, No. 17, pp. 3580-3585, 2018
Non-Patent Document 4: D. C. Houghton, et al., “Comparison of chemical beam epitaxy and metalorganic chemical vapour deposition for highly strained multiple quantum well InGaAsP/InP 1.5 μm lasers”, J. Crystal Growth, Vol. 136, pp. 56-63, 1994

### SUMMARY OF THE INVENTION

### Problem to be Solved by the Invention

Unfortunately, even currently, it is extremely difficult to form a high-quality Ge absorption layer thicker than 1 μm due to lattice constant mismatch of the Ge absorption layer grown on a Si substrate. Namely, SiGe-APDs using Si substrates have problems in reliability and manufacturing technology. From the viewpoint of high reliability, an AlInAs multiplication layer above an InP substrate, which is made of a group III-V compound semiconductor material, is excellent as a multiplication layer for electron multiplication-type APDS, but its noise performance is inferior to that of APDs with a Si multiplication layer.

Consequently, in order to form the Si multiplication layer above the InP substrate that can be expected to reduce noise, for example, in the APD described in Patent Document 2, an attempt has been made to form a light absorption layer using the InP substrate and a group III-V compound semiconductor with a lattice constant that is an integer ratio to the lattice constant of Si, and then to form the Si multiplication layer above the InP substrate. Unfortunately, in such a structure, not only the Si multiplication layer but also the light absorption layer made of the group III-V compound semiconductor itself is lattice-mismatched, thereby making it difficult to form high level of crystal quality that can function as a multiplication layer, and there are concerns about the reliability of APDs.

Furthermore, in the semiconductor light-receiving device described in Patent Document 3, it is described that an amorphous InGaAs layer is formed as a light absorption layer after a high-quality Si multiplication layer is grown above the Si substrate without using the InP substrate. Unfortunately, in such a device structure and a manufacturing method, the high density of crystal defects within the amorphous InGaAs layer results in a large dark current caused by the crystal defects, and there are also concerns about the reliability of APDs.

In addition to the above, devices (especially RF devices) with excellent characteristics have been achieved by depositing Si itself in two dimensions by using a technology called delta doping, which involves high-concentration doping of Si in two dimensions, thereby depositing Si itself in two dimensions, as described in Non-Patent Document 2. Unfortunately, since APDs require a layer thickness of several tens of nanometers in order to generate avalanche amplification, δ doping has a problem that thickening is not possible due to deterioration of the surface condition, etc.

Recently, a paper has been published (Non-Patent Document 3) describing a technology called Digital Alloy, which enables the control of crystal growth at the atomic layer level in compound semiconductor materials composed of group III-V compound semiconductors, thereby enabling the formation of semiconductors with material properties different from those of conventional materials. Applying digital alloy technology, it is possible to achieve structures with material properties that have never been achieved before by controlling the layer thickness of two materials with different lattice constants at the atomic layer level.

Unfortunately, good crystal quality cannot be obtained simply by selecting and stacking crystal materials due to crystal defects caused by structural-origin stress due to lattice mismatch and other factors. In order to achieve an APD that is both high-speed and high-quality, it is necessary to form a silicon (Si) layer with a layer thickness that can be used for avalanche multiplication above a compound semiconductor substrate, and this is possible by appropriately selecting the materials to be stacked at the atomic layer level.

The present disclosure has been made to solve the above-mentioned problems, and an object of the present disclosure is to provide a semiconductor light-receiving device having low noise and excellent reliability, and a method for manufacturing the same.

### Means to Solve the Problem

A semiconductor light-receiving device according to the present disclosure includes: a semiconductor substrate; a digital alloy-type multiplication layer formed above the semiconductor substrate and having a digital alloy structure, the digital alloy structure comprising alternately stacked multiple layers of a plurality of first semiconductor layers and a plurality of second semiconductor layers, the first semiconductor layer comprising a superlattice layer made of IV group atoms, the second semiconductor layer having a bandgap energy larger than a bandgap energy of the first semiconductor layer; an electric field control layer formed above the digital alloy-type multiplication layer and configured to relax an electric field; and a light absorption layer formed above the electric field control layer and configured to absorb incident light.

A method for manufacturing a semiconductor light-receiving device according to the present disclosure includes: a step of sequentially epitaxially crystal-growing above an n-type InP substrate, by an MOVPE method, an n-type AlInAs buffer layer, a digital alloy-type multiplication layer having a digital alloy structure comprising alternately stacked multiple layers of a plurality of Si layers or Si-containing layers with each thickness of N times (1≤N≤20) a thickness of a monolayer and a plurality of AlAs layers with each thickness of M times (1≤M≤20) a thickness of a monolayer, a p-type AlInAs electric field control layer, an n-type InGaAs light absorption layer, an i-type AlInAs window layer, an n-type InP window layer, and a p-type InGaAs contact layer; and a step of forming a Zn selective diffusion region in the n-type InP window layer and a part of the i-type AlInAs window layer.

### Effect of the Invention

The semiconductor light-receiving device and the manufacturing method for the semiconductor light-receiving device according to the present disclosure make it possible to form a high-quality digital alloy-type multiplication layer containing group IV atoms above a semiconductor substrate, thus providing an effect that the semiconductor light-receiving device having low noise and excellent reliability can be achieved, and the semiconductor light-receiving device can be easily manufactured.

### BRIEF DESCRIPTION OF THE DRAWINGS

FIG. 1 is a cross-sectional view showing a device structure of a semiconductor light-receiving device according to Embodiment 1;

FIG. 2 is a diagram showing the relationship between the excess noise coefficient and the multiplication factor;

FIG. 3 is a cross-sectional view showing a device structure of a semiconductor light-receiving device according to Embodiment 2;

FIG. 4 is a diagram showing the calculation results of the effective stress τ when the composition ratio of Si and AlAs is changed in a digital alloy-type stacked structure made of Si and AlAs in the semiconductor light-receiving device according to Embodiment 2;

FIG. 5 is a cross-sectional view showing a device structure of a semiconductor light-receiving device according to Embodiment 3;

FIG. 6 is a cross-sectional view showing a device structure of a semiconductor light-receiving device according to Embodiment 4;

FIG. 7 is a diagram showing the relationship between the Si sheet carrier concentration and the amount of Si material supplied;

FIG. 8 is a cross-sectional view showing a device structure of a semiconductor light-receiving device according to Embodiment 5.

### DESCRIPTION OF EMBODIMENTS

### Embodiment 1

### Device Structure of Semiconductor Light-Receiving Device According to Embodiment 1

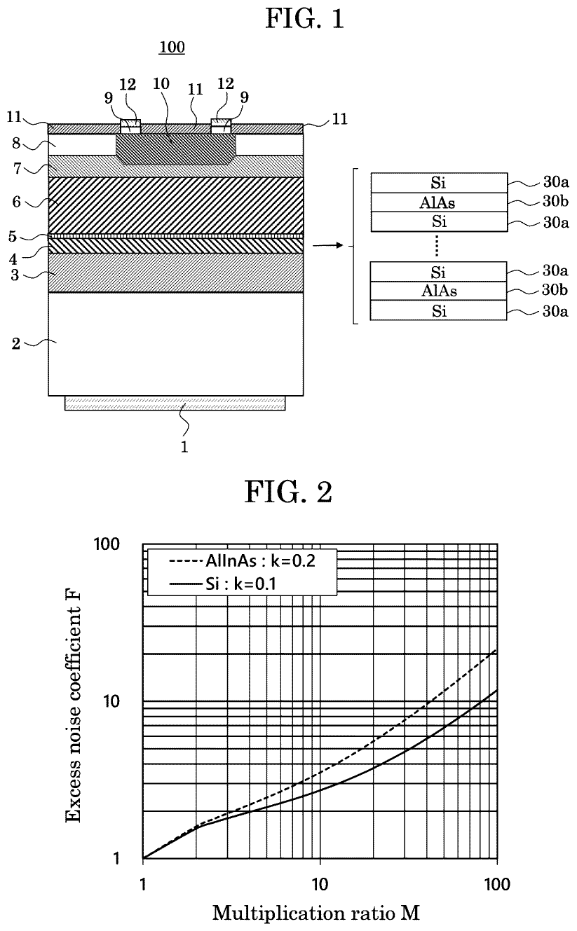

FIG. 1 is a cross-sectional view showing a device structure of a semiconductor light-receiving device 100 according to Embodiment 1. An example of the semiconductor light-receiving device 100 according to Embodiment 1 is an SACM-type APD.

The semiconductor light-receiving device 100 according to Embodiment 1 includes: an n-type AlInAs buffer layer 3 having a carrier concentration of 1×10¹⁸ to 5×10¹⁸ cm⁻³ and a thickness of 0.1 to 0.5 μm; an i-type Si—AlAs digital alloy-type multiplication layer 4 that has a thickness of 0.05 to 0.2 μm and has a digital alloy structure comprising alternately stacked multiple layers of a plurality of i-type Si layers (for example, a thickness of two MLs) and a plurality of i-type AlAs layers (for example, a thickness of two MLs); a p-type AlInAs electric field control layer 5 having a carrier concentration of 0.5×10¹⁸ to 1×10¹⁸ cm⁻³ and a thickness of 0.05 to 0.15 μm; an n-type InGaAs light absorption layer 6 having a carrier concentration of 1×10¹⁵ to 5×10¹⁵ cm⁻³ and a thickness of 1.0 to 1.5 μm; an i-type AlInAs window layer 7 having a thickness of 0.05 to 1 μm; an n-type InP window layer 8 having a carrier concentration of 0.1×10¹⁵ to 5×10¹⁵ cm⁻³ and a thickness of 0.5 to 1.0 μm; and a p-type InGaAs contact layer 9 with a circular shape having a carrier concentration of 1×10¹⁸ to 5×10¹⁸ cm⁻³ and a thickness of 0.1 to 0.5 μm, which are sequentially formed above an n-type InP substrate 2.

The semiconductor light-receiving device 100 according to Embodiment 1 further includes: a Zn selective diffusion region 10 (p-type conductive region) provided in the n-type InP window layer 8 and a part of the i-type AlInAs window layer 7; a SiNx surface protection film 11 provided on the surface of the n-type InP window layer 8 including the surface of the Zn selective diffusion region 10; an n-type electrode 1 provided on the back side of the n-type InP substrate 2; and a p-type electrode 12 provided on the surface of the p-type InGaAs contact layer 9 with the circular shape.

The semiconductor light-receiving device 100 according to Embodiment 1 is characterized in that the multiplication layer is composed of the i-type Si—AlAs digital alloy-type multiplication layer 4 that has the digital alloy structure comprising alternately stacked multiple layers of the plurality of i-type Si layers and the plurality of i-type AlAs layers. In the description of the respective embodiments, the composition ratios of AlInAs and InGaAs constituting each layer except the multiplication layer are not specified, but it is preferable that both have composition ratios that are lattice-matched to the n-type InP substrate 2.

The i-type Si layer described above refers to a silicon superlattice layer having a thickness N times (1≤N≤20) a thickness of a silicon monolayer. The i-type Si layer is also referred to as a first semiconductor layer 30a, the i-type AlAs layer is also referred to as a second semiconductor layer 30b, and the i-type Si—AlAs digital alloy-type multiplication layer 4 is simply referred to as a digital alloy-type multiplication layer.

In the description above, as an example of the i-type Si—AlAs digital alloy-type multiplication layer 4, a multiplication layer in which a plurality of i-type Si layers each having a thickness of two monolayers (MLs) and a plurality of i-type AlAs layers each having a thickness of two MLs are alternately stacked a plurality of times is given. However, the i-type Si layer may have a thickness within a range of N times (1≤N≤20) the thickness of the monolayer, and the i-type AlAs layer may have a thickness within a range of M times (1≤M≤20) the thickness of the monolayer. More preferably, the i-type Si layer may have a thickness within a range of N times (1≤N≤6) the thickness of the monolayer, and the i-type AlAs layer may have a thickness within a range of M times (1≤M≤6) the thickness of the monolayer. For the i-type Si—AlAs digital alloy-type multiplication layer 4, when the i-type Si layer and the i-type AlAs layer are alternately stacked a plurality of times, the number of stacking layers is preferably in the range of 5 to 300.

### Method for Manufacturing a Semiconductor Light-Receiving Device According to Embodiment 1

The semiconductor light-receiving device 100 according to Embodiment 1 can be manufactured by forming semiconductor layers above the InP substrate using a crystal growth method such as metal organic vapor phase epitaxy (MOVPE) or molecular beam epitaxy (MBE). A method for manufacturing an SACM-type APD, which is an example of the semiconductor light-receiving device 100 according to Embodiment 1, will be described below.

The n-type AlInAs buffer layer 3, the i-type Si—AlAs digital alloy-type multiplication layer 4 that has the digital alloy structure comprising alternately stacked multiple layers of the plurality of i-type Si layers (a thickness of two MLs) and a plurality of i-type AlAs layers (a thickness of two MLs), the p-type AlInAs electric field control layer 5, the n-type InGaAs light absorption layer 6, the i-type AlInAs window layer 7, the n-type InP window layer 8, and the p-type InGaAs contact layer 9 are sequentially grown on the surface of the n-type InP substrate 2 by the MOVPE method.

When the MOVPE method is used as the epitaxial crystal growth method, the crystal growth temperature is preferably around 550° C., but may also be within the temperature range from 500° C. to 600° C.

In the wafer process after the epitaxial crystal growth, in order to form the device structure necessary to function as an SACM-type APD, the device region is processed, films are deposited, and electrodes are formed using reactive ion etching, CVD (chemical vapor deposition), and deposition. The wafer process will be described in detail below.

A SiOx film is deposited on the surface of the wafer after the epitaxial crystal growth by CVD or the like. The SiOx film is an insulating film and functions as a diffusion mask.

A circular pattern mask with a diameter of 20 μm is used to pattern the SiOx film using photolithography and etching techniques, and then a circular opening is formed in the SiOx film. Using the SiOx film as a diffusion mask, the Zn selective diffusion region 10 is formed in the n-type InP window layer 8 and the part of the i-type AlInAs window layer 7 by a method such as diffusing zinc (Zn) from the opening into the semiconductor layers. The front end of the Zn selective diffusion region 10 in the semiconductor layers is located in the i-type AlInAs window layer 7. The Zn selective diffusion region 10 functions as a p-type conductive region. After the formation of the Zn selective diffusion region 10, the SiOx film is removed by wet etching or dry etching.

Next, the p-type InGaAs contact layer 9 is processed by reactive ion etching or the like such that the p-type InGaAs contact layer 9 remains in the circular shape with a width of about 3.0 to 5.0 μm on the Zn selective diffusion region 10 using photolithography and etching techniques.

After processing the p-type InGaAs contact layer 9, a SiNx surface protection film 11 is deposited on the surface of the wafer by CVD or the like. Subsequently, only the SiNx surface protection film 11 on the surface of the p-type InGaAs contact layer 9 is removed using photolithography and etching techniques. The Six surface protection film 11 also functions as an anti-reflection film.

A metal material such as Ti/Au is deposited on the surface of the p-type InGaAs contact layer 9 by vapor deposition or the like to form the p-type electrode 12.

Finally, the back side of the n-type InP substrate 2 is ground, and then a metal material such as AuGeNi is deposited by vapor deposition or the like to form the n-type electrode 1.

The above describes the method for manufacturing the SACM-type APD which is an example of the semiconductor light-receiving device 100 according to Embodiment 1.

### Operation of Semiconductor Light-Receiving Device According to Embodiment 1

The operation of the SACM-type APD, which is an example of the semiconductor light-receiving device 100 according to Embodiment 1 manufactured by the above manufacturing method, will be described below.

First, a reverse bias voltage is externally applied to the SACM-type APD, which is an example of the semiconductor light-receiving device 100, so that the n-type electrode 1 provided on the back side of the n-type InP substrate 2 is positive and the p-type electrode 12 provided on the front side is negative. Note that the reverse bias voltage is set to a voltage value that sufficiently generates avalanche amplification.

When light having a wavelength of 1.3 μm or 1.55 μm, which is a wavelength band used in optical communication, is incident on the p-type electrode 12 side of the SACM-type APD with a reverse bias voltage applied, into the Zn selective diffusion region 10, which is a p-type conductive region, the light is absorbed in the n-type InGaAs light absorption layer 6 and then photocarriers (electron-hole pairs) are generated. In the state where the reverse bias voltage is applied, the electron moves to the n-type electrode 1 side and the hole moves to the p-type electrode 12 side, respectively.

In the SACM-type APD to which the reverse bias voltage is applied, the electric field intensity is controlled by the p-type AlInAs electric field control layer 5 such that avalanche amplification occurs when electrons are conducted in the i-type Si—AlAs digital alloy-type multiplication layer 4. In the i-type Si—AlAs digital alloy-type multiplication layer 4, electrons are ionized to generate new electron-hole pairs, and the newly generated electrons and holes cause ionization in a chain reaction, whereby electrons and holes are amplified in an avalanche manner, that is, avalanche amplified. In other words, electrons, which are photocarriers, are multiplied by the avalanche amplification effect in the i-type Si—AlAs digital alloy-type multiplication layer 4, thereby received optical signals can be amplified.

### Action of Semiconductor Light-Receiving Device According to Embodiment 1

The characteristics of a semiconductor light-receiving device can be expressed by the signal-to-noise ratio, that is, the S/N ratio. An APD with excellent light-receiving sensitivity has a large S/N ratio. The S/N ratio of a semiconductor light-receiving device can be expressed by the following Expression (1), where iₛ is the signal intensity due to a photocurrent generated by light absorption, i_{Ns} is the shot noise which is a noise component generated inside the semiconductor light-receiving device such as a dark current, and i_{Nt} is the thermal noise generated by thermal noise amplitude caused by peripheral circuits.

$$[ Mathematical 1 ]$$

$$S / N = \frac{{i}_{s}^{2}}{{i}_{Ns}^{2} + {i}_{Nt}^{2}} \qquad ( 1 )$$

In particular, in the case where the semiconductor light-receiving device is an APD, the signal intensity is increases due to the multiplication of photocarriers generated by light absorption, and the S/N ratio can be increased, thereby enabling signal reception in long-distance communication.

Next, assuming that the elementary charge of an electron is q, the avalanche multiplication factor is M, the average current value flowing in the avalanche region of the APD is Iₚ, the dark current multiplied in the avalanche region is I_{dM}, the excess noise factor is x, the band is B, the Boltzmann constant is k, the temperature is T, and the external circuit resistance is R_{L}, the S/N ratio is calculated using the following Expression (2).

$$[ Mathematical 2 ]$$

$$S / N = \frac{{I}_{p}^{2} {M}^{2}}{2 q ( {I}_{p} + {I}_{dM} ) {M}^{2 + x} B + 4 kT B / {R}_{L}} \qquad ( 2 )$$

The main factors that degrade the S/N ratio in Expression (2) are the multiplied dark current I_{dM}, which is determined by the component of the APD in the denominator side, and the excess noise factor x, which is included in the power of the multiplication factor M. Since the dark current I_{dM} is the dark current generated when photocarriers are multiplied, the dark current I_{dM} greatly depends on the crystal quality of the APD. In particular, in SiGe-APDs, the dark current caused by crystal defects in the Ge absorption layer due to the difference in lattice constant with Si increases, causing the S/N ratio of the APD to deteriorate.

Regarding the excess noise factor x, which affects another characteristic of the APD, the following relationship is established between the excess noise coefficient F and the multiplication factor M, as expressed in the following Expression (3).

$$[ Mathematical 3 ]$$

$$F = {M}^{x} \qquad ( 3 )$$

It can be understood from Expression (3) that if the excess noise coefficient F is known, the excess noise factor x can be calculated using the multiplication factor M. In the SACM-type APD, the excess noise coefficient F is expressed by the following Expression (4) using the collision ionization rate ratio k, which indicates the multiplication ratio of holes and electrons.

$$[ Mathematical 4 ]$$

$$F = M [ 1 - ( 1 - k ) {( \frac{M - 1}{M} )}^{2} ] \qquad ( 4 )$$

It can be understood from Expression (4) that the excess noise coefficient F becomes smaller as the collisional ionization rate ratio k becomes smaller, and the excess noise factor x also becomes smaller, resulting in a larger S/N ratio, and thus, excellent noise characteristics. FIG. 2 shows the relationship between the excess noise coefficient F and the multiplication ratio M. In general, the collision ionization rate ratio k is a value specific to the material, and for Si, k=0.1, which is a smaller value than AlInAs, k=0.2. Therefore, as shown in FIG. 2, Si is more advantageous when considering noise characteristics.

Meanwhile, since the absorption layer of SiGe-APDs is made of Ge, as mentioned above, the shot noise (I_{dM} component) caused by crystal defects increases, and thus depending on the crystal quality and/or variation in characteristics caused by manufacturing, problems often occur where the desired S/N ratio cannot be obtained.

On the other hand, in the electron multiplication-type APD using the InP substrate, the absorption layer is made of InGaAs, and the multiplication layer is made of AlInAs. Since both crystals are lattice-matched to the InP substrate, crystal defects are less likely to occur, making it possible to manufacture an APD with low noise and excellent reliability.

In order to further improve the S/N ratio of APDs, it is possible to use the digital alloy technology disclosed in Non-Patent Document 2, that is, a technology in which different materials are stacked at the atomic layer level. The digital alloy technology makes it possible to grow a multiplication layer with a smaller collision rate ratio k than conventional materials by stacking group III-V compound semiconductors such as AlAs and InAs at the atomic layer level with Si in the multiplication layer.

Since Si has a lattice constant smaller than a lattice constant of InP or GaAs, which are semiconductor materials used in the optical communication band, the lattice constant of group III-V compound semiconductor materials requires a larger value than that of Si when growing a stacked structure such as a multiplication layer containing Si. In addition, a high-quality absorption layer can be achieved simultaneously with the formation of the multiplication layer, thereby the shot noise can be suppressed, making it possible to stably manufacture an APD with higher sensitivity than conventional SACM-type APDs.

In Embodiment 1, as an example, the multiplication layer is composed of the material containing Si and the AlAs layer which is the semiconductor material different from Si. A same effect can be obtained when a compound semiconductor material composed of a group III atomic material and a group V atomic material such as InP, GaP, AlP, InAs, GaAs, InSb, GaSb, and AlSb is used as the multiplication layer material. Moreover, the crystal material is not limited to a binary compound, and a same effect can be obtained when a ternary or a quaternary compound semiconductor material, for example, a compound semiconductor such as InGaAs, AlInAs, GaAsSb, AlGaInAs, and AlGaAsSb, is stacked at the atomic layer level.

As an example of the thickness of the layers constituting the digital alloy structure, a structure in which layers are stacked in units of two MLs is given. However, any combination of layer thickness is acceptable as long as the layer thickness is a critical thickness of 5 nm or less, for example, which allows crystal growth of the required multiplication layer material without causing crystal defects to the underlying substrate. The Si—AlAs digital alloy-type multiplication layer may be an n-type Si—AlAs digital alloy-type multiplication layer or a p-type Si—AlAs digital alloy-type multiplication layer by doping n-type or p-type impurities into the entire Si—AlAs digital alloy-type multiplication layer, instead of the i-type, that is, undoping, as shown in the above example.

In the above example, the Zn selective diffusion region 10, which is the p-type conductive region, is formed by Zn diffusion. However, if elements that give p-type conductivity are used, it is not necessary to use Zn, and Cd or Be can be used instead. The method of Zn diffusion may be a solid phase diffusion method using ZnO or a Zn vapor phase diffusion method using a crystal growth furnace. Alternatively, instead of the Zn selective diffusion region 10, a p-type contact layer may be grown by crystal growth.

In the above-described example, a surface-incident type structure in which light to be detected is incident on the Zn selective diffusion region 10, which is a p-type conductive region, from the p-type electrode 12 side has been described. Contrary to the surface-incident type structure, a same effect can be achieved in a back-side-incident type structure in which the n-type electrode 1 on the back side of the n-type InP substrate 2 is opened using a circular pattern and light is incident on the n-type InP substrate 2 side. Furthermore, a same effect can be achieved in an edge-incident type structure in which light is incident on the n-type light absorption layer from the edge side.

### Effects of Embodiment 1

As described above, in the semiconductor light-receiving device and the method for manufacturing the semiconductor light-receiving device according to Embodiment 1, the multiplication layer comprises the Si—AlAs digital alloy-type multiplication layer comprising alternately stacked multiple layers of a plurality of Si layers in which each Si layer is composed of a silicon superlattice layer and a plurality of AlAs layers, thus providing an effect that a semiconductor light-receiving device having low noise and excellent reliability can be obtained and such a semiconductor light-receiving device can be easily manufactured.

### Embodiment 2

### Device Structure of Semiconductor Light-Receiving Device According to Embodiment 2

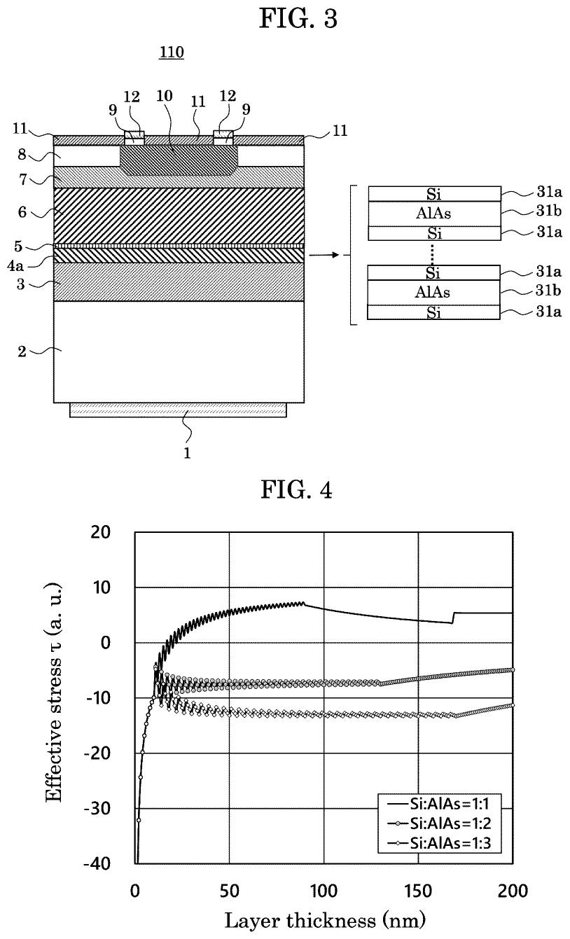

FIG. 3 is a cross-sectional view showing a device structure of a semiconductor light-receiving device 110 according to Embodiment 2. An example of the semiconductor light-receiving device 110 according to Embodiment 2 is an SACM-type APD.

The semiconductor light-receiving device 110 according to Embodiment 2 includes: an n-type AlInAs buffer layer 3 having a carrier concentration of 1×10¹⁸ to 5×10¹⁸ cm⁻³ and a thickness of 0.1 to 0.5 μm; an i-type Si—AlAs digital alloy-type multiplication layer 4a that has a thickness of 0.05 to 0.2 μm and has a digital alloy structure comprising alternately stacked multiple layers of a plurality of i-type Si layers (for example, a thickness of two MLs) and a plurality of i-type AlAs layers (for example, a thickness of four MLs); a p-type AlInAs electric field control layer 5 having a carrier concentration of 0.5×10¹⁸ to 1×10¹⁸ cm⁻³ and a thickness of 0.05 to 0.15 μm; an n-type InGaAs light absorption layer 6 having a carrier concentration of 1×10¹⁵ to 5×10¹⁵ cm⁻³ and a thickness of 1.0 to 1.5 μm; an i-type AlInAs window layer 7 having a thickness of 0.05 to 1 μm; an n-type InP window layer 8 having a carrier concentration of 0.1×10¹⁵ to 5×10¹⁵ cm⁻³ and a thickness of 0.5 to 1.0 μm; and a p-type InGaAs contact layer 9 with a circular shape having a carrier concentration of 1×10¹⁸ to 5×10¹⁸ cm⁻³ and a thickness of 0.1 to 0.5 μm, which are sequentially formed above an n-type InP substrate 2.

The semiconductor light-receiving device 110 according to Embodiment 2 further includes: a Zn selective diffusion region 10 (p-type conductive region) provided in the n-type InP window layer 8 and a part of the i-type AlInAs window layer 7; a SiNx surface protection film 11 provided on the surface of the n-type InP window layer 8 including the surface of the Zn selective diffusion region 10; an n-type electrode 1 provided on the back side of the n-type InP substrate 2; and a p-type electrode 12 provided on the surface of the p-type InGaAs contact layer 9 with the circular shape.

The semiconductor light-receiving device 110 according to Embodiment 2 is characterized in that the the multiplication layer is composed of i-type Si—AlAs digital alloy-type multiplication layer 4a having the digital alloy structure that comprises alternately stacked multiple layers of the plurality of i-type Si layers each having a thickness N times (1≤N≤20) a thickness of a monolayer and the plurality of i-type AlAs layers each having a thickness M times (1≤M≤20) a thickness of a monolayer, and has a relationship (N<M) in which the number of monolayers M constituting the i-type AlAs layer is larger than the number of monolayers N constituting the i-type Si layer.

The i-type Si layer described above refers to a silicon superlattice layer having a thickness N times (1≤N≤20) a thickness of a silicon monolayer. The i-type Si layer is also referred to as a first semiconductor layer 31a, the i-type AlAs layer is also referred to as a second semiconductor layer 31b, and the i-type Si—AlAs digital alloy-type multiplication layer 4a is simply referred to as a digital alloy-type multiplication layer.

In the description above, as an example of the i-type Si—AlAs digital alloy multiplication layer 4a, a multiplication layer in which a plurality of i-type Si layers each having a thickness of two monolayers (MLs) and a plurality of i-type AlAs layers each having a thickness of four MLs, are alternately stacked a plurality of times is given. Preferably, the relationship (N<M) that the number of monolayers M constituting the i-type AlAs layer is larger than the number of monolayers N constituting the i-type Si layer should be satisfied, and the i-type Si layer may have a thickness within a range of N times (1≤N≤20) the thickness of the monolayer, and the i-type AlAs layer may have a thickness within a range of M times (1≤M≤20) the thickness of the monolayer. More preferably, the i-type Si layer may have a thickness within a range of N times (1≤N≤6) the thickness of the monolayer, and the i-type AlAs layer may have a thickness within a range of M times (1≤M≤6) the thickness of the monolayer. For the i-type Si—AlAs digital alloy-type multiplication layer 4, when the i-type Si layer and the i-type AlAs layer alternately stacked a plurality of times, the number of stacking layers is preferably in the range of 5 to 300.

### Method for Manufacturing a Semiconductor Light-Receiving Device According to Embodiment 2

Since the method for manufacturing the semiconductor light-receiving device 110 according to Embodiment 2 is almost the same as the method for manufacturing the semiconductor light-receiving device 100 according to Embodiment 1, a detailed description of the manufacturing method is omitted.

### Operation of Semiconductor Light-Receiving Device According to Embodiment 2

A layer structure of APDs having a total thickness of about 2 μm, from the electric field control layer to the p-type contact layer, is generally grown on the upper side of the multiplication layer. If crystal defects occur inside the crystal constituting the layer structure, the dark current increases and thus the shot noise increases, causing the S/N ratio of APDs to deteriorate and raising concerns about reliability.

The multiplication layer formed using the digital alloy technology disclosed in the present disclosure is formed by alternately stacking layers of Si whose lattice constant does not match the lattice constant of the semiconductor substrate and other semiconductor materials at the atomic layer level. Therefore, it is necessary to reduce the stress in the entire crystal growth layer by alternately stacking layers with compressive strain and layers with tensile strain.

In the structure in which two different materials are alternately and repeatedly stacked, the effective stress τ on a basis of the mechanical equilibrium model, which is a measure of the force at which dislocations occur, can be calculated by using the following Expression (5) on a basis of the description in Non-Patent Document 4.

$$[ Mathematical 5 ]$$

$$τ = A \{ μ \frac{Nhx + ( N - 1 ) Hy}{L} - \frac{B}{L} [ ln ( \frac{β}{b} ) ( L + z ) + ln ( \frac{β}{b} ) z + 2 ln ( \frac{L}{L + z} ) ] \} \qquad ( 5 )$$

$$A = 2 cos ψ cos λ \frac{1 + v}{1 - v}$$

$$B = \frac{{μ}_{x} {μ}_{y}}{{μ}_{x} + {μ}_{y}} \frac{b ( 1 - v {cos}^{2} θ )}{4 π ( 1 + v ) cos λ}$$

The meanings of the symbols in Expression (5) are as follows:
Ψ: Angle between interface and slip plane
λ: Angle between dislocation line and Burger spectrum
ν: Poisson's ratio
μₓ: Shear coefficient of compressive strain layer
μ_{y}: Shear coefficient of tensile strain layer
μ_{xy}: Average shear coefficient of repeated staking
b: Burger spectrum
θ: Angle between dislocation line and Burger spectrum
β: Core parameter
x: Strain amount of compression strained layer
h: Thickness of compression strained layer
y: Strain amount of tension strained layer
H: Thickness of tension strained layer
Z: Thickness of strain relaxation layer
N: Number of compression strained layers
L: Calculated value of Nh+(N−1) H

If the calculated effective stress τ is normalized and the layer structure is configured such that the effective stress τ is zero or less, high-quality APDs that do not generate transitions can be grown. FIG. 4 shows the calculated effective stress τ in the case where the composition ratio of the Si layers and the AlAs layers is changed in a digital alloy-type stacked structure composed of the Si layers and the AlAs layers. In the case where the Si layer is considered as one monolayer and the AlAs layer is changed one to three monolayers, it can be understood that increasing the stacking composition ratio of the AlAs layer relative to the Si layer reduces the effective stress τ. In FIG. 4, the vertical axis is an arbitrary unit of the effective stress τ, and the horizontal axis is the thickness of the stacked structure.

When growing a digital alloy-type multiplication layer containing Si, the effective stress τ acts in a way that relaxes the stress of the entire stacked structure by layering materials with a larger lattice constant than Si. However, since the materials constituting the stacked structure are themselves lattice-mismatched systems, the effective stress τ applied to the entire semiconductor light-receiving device gradually increases. Therefore, it is necessary to control the thickness of the entire stacked structure below a critical thickness where the crystal defects do not occur.

In Embodiment 2, a combination of the Si layer and the AlAs layer is described as an example of the digital alloy-type multiplication layer. Instead of the AlAs layer, other group III-V compound semiconductor materials other than AlAs may be used. The group III-V compound semiconductor material may be a ternary compound semiconductor or a quaternary compound semiconductor. The digital alloy-type multiplication layer may not be undoped, but may be doped with, for example, p-type or n-type doping.

### Effects of Embodiment 2

As described above, in the semiconductor light-receiving device according of Embodiment 2, the multiplication layer is composed of the Si—AlAs digital alloy-type multiplication layer that comprises alternately stacked multiple layers of the plurality of Si layers each having a thickness N times a thickness of a monolayer and the plurality of AlAs layers each having a thickness M times a thickness of a monolayer, and has a relationship in which the number of monolayers M constituting the AlAs layer is larger than the number of monolayers N constituting the Si layer, thus providing an effect that a semiconductor light-receiving device having low noise and excellent reliability can be obtained.

### Embodiment 3

### Device Structure of Semiconductor Light-Receiving Device According to Embodiment 3

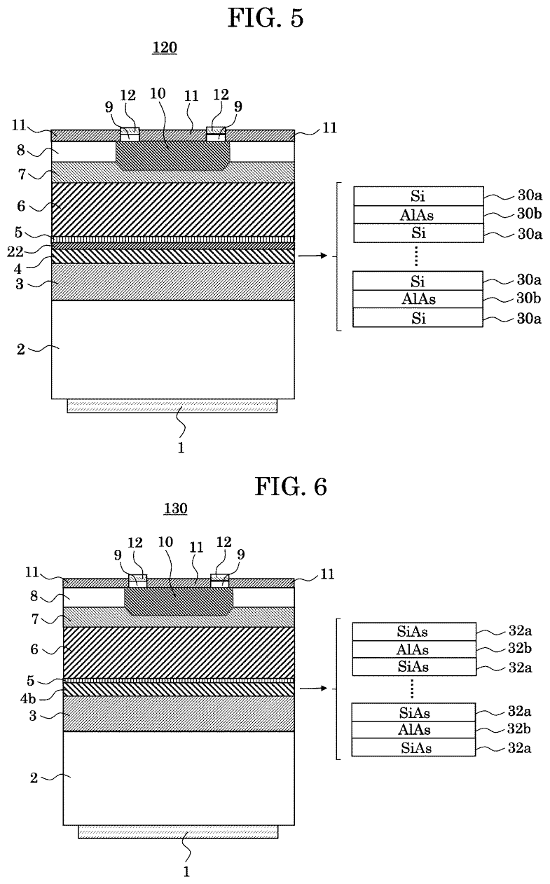

FIG. 5 is a cross-sectional view showing a device structure of a semiconductor light-receiving device 120 according to Embodiment 3. An example of the semiconductor light-receiving device 120 according to Embodiment 3 is an SACM-type APD.

The semiconductor light-receiving device 120 according to Embodiment 3 includes: an n-type AlInAs buffer layer 3 having a carrier concentration of 1×10¹⁸ to 5×10¹⁸ cm⁻³ and a thickness of 0.1 to 0.5 μm; an i-type Si—AlAs digital alloy-type multiplication layer 4 that has a thickness of 0.05 to 0.2 μm and has a digital alloy structure comprising alternately stacked multiple layers of a plurality of i-type Si layers (for example, a thickness of two MLs) and a plurality of i-type AlAs layers (for example, a thickness of two MLs); an i-type AlₓGa_{y}In_{1-x-y}As (x=0.25, y=0.218) transition layer 22 having a thickness of 15 nm; a p-type AlInAs electric field control layer 5 having a carrier concentration of 0.5×10¹⁸ to 1×10¹⁸ cm⁻³ and a thickness of 0.05 to 0.15 μm; an n-type InGaAs light absorption layer 6 having a carrier concentration of 1×10¹⁵ to 5×10¹⁵ cm⁻³ and a thickness of 1.0 to 1.5 μm; an i-type AlInAs window layer 7 having a thickness of 0.05 to 1 μm; an n-type InP window layer 8 having a carrier concentration of 0.1×10¹⁵ to 5×10¹⁵ cm⁻³ and a thickness of 0.5 to 1.0 μm; and a p-type InGaAs contact layer 9 with a circular shape having a carrier concentration of 1×10¹⁸ to 5×10¹⁸ cm⁻³ and a thickness of 0.1 to 0.5 μm, which are sequentially formed above an n-type InP substrate 2.

The semiconductor light-receiving device 120 according to Embodiment 3 further includes: a Zn selective diffusion region 10 (p-type conductive region) provided in the n-type InP window layer 8 and a part of the i-type AlInAs window layer 7; a SiNx surface protection film 11 provided on the surface of the n-type InP window layer 8 including the surface of the Zn selective diffusion region 10; an n-type electrode 1 provided on the back side of the n-type InP substrate 2; and a p-type electrode 12 provided on the surface of the p-type InGaAs contact layer 9 with the circular shape.

The semiconductor light-receiving device 120 according to Embodiment 3 is characterized in that the multiplication layer is the i-type Si—AlAs digital alloy-type multiplication layer 4 comprising the digital alloy structure, and the i-type AlₓGa_{y}In_{1-x-y}As transition layer 22 having a thickness of 15 nm is provided between the i-type Si—AlAs digital alloy-type multiplication layer 4 and the p-type AlInAs electric field control layer 5. Note that each layer other than the i-type AlₓGa_{y}In_{1-x-y}As transition layer 22 is identical to each layer of the semiconductor light-receiving device 100 according to Embodiment 1.

### Method for Manufacturing Semiconductor Light-Receiving Device According to Embodiment 3

The method for manufacturing the semiconductor light-receiving device 120 according to Embodiment 3 differs from the method for manufacturing the semiconductor light-receiving device 100 according to Embodiment 1 only in that the i-type AlₓGa_{y}In_{1-x-y}As transition layer 22 is further grown between the i-type Si—AlAs digital alloy-type multiplication layer 4 comprising the digital alloy structure and the p-type AlInAs electric field control layer 5 during epitaxial crystal growth. Accordingly, a detailed description of the manufacturing method is omitted.

### Action of Semiconductor Light-Receiving Device According to Embodiment 3

In an electron multiplication-type APD, the electrons of the photocarriers generated when light enters the APD are conducted from the light absorption layer to the multiplication layer in the layers to which reverse bias is applied, and after reaching the multiplication layer, the electrons are amplified by avalanche multiplication. The application of the multiplication layer containing Si changes the amount of band discontinuity generated between the absorption layer and the multiplication layer, which may act as a band barrier and inhibit the high-speed response. Band discontinuity is a particularly serious disturbance to high-speed response when the multiplication factor is small with low voltage.

Therefore, in the semiconductor light-receiving device 120 according to Embodiment 3, the transition layer made of AlₓGa_{y}In_{1-x-y}As (x=0.25, y=0.22), which is a quaternary compound semiconductor material having a bandgap energy value intermediate between a bandgap energy of the multiplication layer and a bandgap energy of the electric field control layer, and having a thickness of about 15 nm is inserted between the i-type Si—AlAs digital alloy-type multiplication layer 4 and the p-type AlInAs electric field control layer 5, thereby reducing the band barrier when electrons conduct to the multiplication layer. As a result, it is possible to achieve high-speed response in the semiconductor light-receiving device 120. In addition to these effects, it is also possible to expect an effect of partially relaxing the effective stress τ of the entire layer structure by growing a crystal layer having a composition different from that of the multiplication layer above the multiplication layer.

In Embodiment 3, the i-type AlₓGa_{y}In_{1-x-y}As layer is used as an example of the transition layer, but other compound semiconductor materials may be used as long as the material has an intermediate bandgap energy for each bandgap energy of the absorption layer, the electric field control layer, and the multiplication layer. In addition, if the transition layer is composed of a combination of layers having the same composition as the layers constituting the digital alloy structure, crystal growth can be controlled easily. The transition layer may be other than undoped, for example, p-type or n-type doping.

### Effects of Embodiment 3

As described above, in the semiconductor light-receiving device according to Embodiment 3, the i-type AlₓGa_{y}In_{1-x-y}As transition layer is provided between the Si—AlAs digital alloy-type multiplication layer and the p-type AlInAs electric field control layer, thereby the band barrier generated between the Si—AlAs digital alloy-type multiplication layer and the p-type AlInAs electric field control layer is effectively reduced, and the carrier conductivity is improved, thus providing an effect of obtaining a semiconductor light-receiving device capable of high-speed operation.

### Embodiment 4

### Device Structure of Semiconductor Light-Receiving Device According to Embodiment 4

FIG. 6 is a cross-sectional view showing a device structure of a semiconductor light-receiving device 130 according to Embodiment 4. An example of the semiconductor light-receiving device 130 according to Embodiment 4 is an SACM-type APD.

The semiconductor light-receiving device 130 according to Embodiment 4 includes: an n-type AlInAs buffer layer 3 having a carrier concentration of 1×10¹⁸ to 5×10¹⁸ cm⁻³ and a thickness of 0.1 to 0.5 μm; an i-type SiAs—AlAs digital alloy-type multiplication layer 4b that has a thickness of 0.05 to 0.2 μm and has a digital alloy structure comprising alternately stacked multiple layers of a plurality of i-type SiAs layers (for example, a thickness of two MLs) and a plurality of i-type AlAs layers (for example, a thickness of two MLs); a p-type AlInAs electric field control layer 5 having a carrier concentration of 0.5×10¹⁸ to 1×10¹⁸ cm⁻³ and a thickness of 0.05 to 0.15 μm; an n-type InGaAs light absorption layer 6 having a carrier concentration of 1×10¹⁵ to 5×10¹⁵ cm⁻³ and a thickness of 1.0 to 1.5 μm; an i-type AlInAs window layer 7 having a thickness of 0.05 to 1 μm; an n-type InP window layer 8 having a carrier concentration of 0.1×10¹⁵ to 5×10¹⁵ cm⁻³ and a thickness of 0.5 to 1.0 μm; and a p-type InGaAs contact layer 9 with a circular shape having a carrier concentration of 1×10¹⁸ to 5×10¹⁸ cm⁻³ and a thickness of 0.1 to 0.5 μm, which are sequentially formed above an n-type InP substrate 2.

The semiconductor light-receiving device 130 according to Embodiment 4 further includes: a Zn selective diffusion region 10 (p-type conductive region) provided in the n-type InP window layer 8 and a part of the i-type AlInAs window layer 7; a SiNx surface protection film 11 provided on the surface of the n-type InP window layer 8 including the surface of the Zn selective diffusion region 10; an n-type electrode 1 provided on the back side of the n-type InP substrate 2; and a p-type electrode 12 provided on the surface of the p-type InGaAs contact layer 9 with the circular shape.

The semiconductor light-receiving device 130 according to Embodiment 4 is characterized in that the the multiplication layer is composed of i-type SiAs—AlAs digital alloy-type type multiplication layer 4b that has the digital alloy structure comprising alternately stacked multiple layers of the plurality of i-type SiAs layers and the plurality of i-type AlAs layers.

The i-type SiAs layer described above refers to a SiAs superlattice layer having a thickness N times (1≤N≤20) a thickness of a SiAs monolayer that is made of a compound of Si and As. The i-type SiAs layer is also referred to as a first semiconductor layer 32a, the i-type AlAs layer is also referred to as a second semiconductor layer 32b, and the i-type SiAs—AlAs digital alloy-type multiplication layer 4b is simply referred to as a digital alloy-type multiplication layer.

In the description above, as an example of the i-type SiAs—AlAs digital alloy-type multiplication layer 4b, a multiplication layer in which a plurality of i-type SiAs layers each having a thickness of two monolayers (MLs) and a plurality of i-type AlAs layers each having a thickness of two MLs are alternately stacked a plurality of times is given. However, the i-type SiAs layer may have a thickness within a range of N times (1≤N≤20) the thickness of the monolayer, and the i-type AlAs layer may have a thickness within a range of M times (1≤M≤20) the thickness of the monolayer. More preferably, the i-type SiAs layer may have a thickness within a range of N times (1≤N≤6) the thickness of the monolayer, and the i-type AlAs layer may have a thickness within a range of M times (1≤M≤6) the thickness of the monolayer. For the i-type SiAs—AlAs digital alloy-type multiplication layer 4b, when the i-type SiAs layer and the i-type AlAs layer are alternately stacked a plurality of times, the number of stacking layers is preferably in the range of 5 to 300.

### Method for Manufacturing Semiconductor Light-Receiving Device According to Embodiment 4

The semiconductor light-receiving device 130 according to Embodiment 4 can be manufactured by forming each semiconductor layer above the InP substrate using the MOVPE method. A method for manufacturing an SACM-type APD which is an example of the semiconductor light-receiving device 130 according to Embodiment 4 will be described below.

The n-type AlInAs buffer layer 3, the i-type SiAs—AlAs digital alloy-type multiplication layer 4b that has the digital alloy structure comprising alternately stacked multiple layers of the plurality of i-type SiAs layers (a thickness of two MLs) and a plurality of i-type AlAs layers (a thickness of two MLs), the p-type AlInAs electric field control layer 5, the n-type InGaAs light absorption layer 6, the i-type AlInAs window layer 7, the n-type InP window layer 8, and the p-type InGaAs contact layer 9 are sequentially grown on the surface of the n-type InP substrate 2 by the MOVPE method at the crystal growth temperature of 550° C.

When growing the i-type SiAs layer using the MOVPE method, silane (SiH₄), which is a silicon source, and arsine (AsH₃), which is an arsenic source, are used as source gases.

When the MOVPE method is used as the epitaxial crystal growth method, the crystal growth temperature is preferably about 550° C., but may be within the temperature range of 500° C. to 600° C.

Since the wafer process after the epitaxial crystal growth is the same as in Embodiment 1, a detailed description is omitted.

### Operation of Semiconductor Light-Receiving Device According to Embodiment 4

When a multiplication layer containing Si is stacked at the atomic layer level, it is sometimes difficult to form a single Si layer depending on the crystal growth method. In the MOVPE method, it is particularly difficult to form the single Si layer in the crystal growth furnace. As a countermeasure, for example, not only silane (SiH₄), which is the source gas for Si material, but also arsine (AsH₃) or phosphine (PH₃), which is the source gas for group V atomic materials, are simultaneously introduced into the crystal growth furnace and reacted to form a layer consisting of a compound such as a SiAs layer or a SiP layer, so that a layer can be formed more easily than a layer consisting of a single Si material.

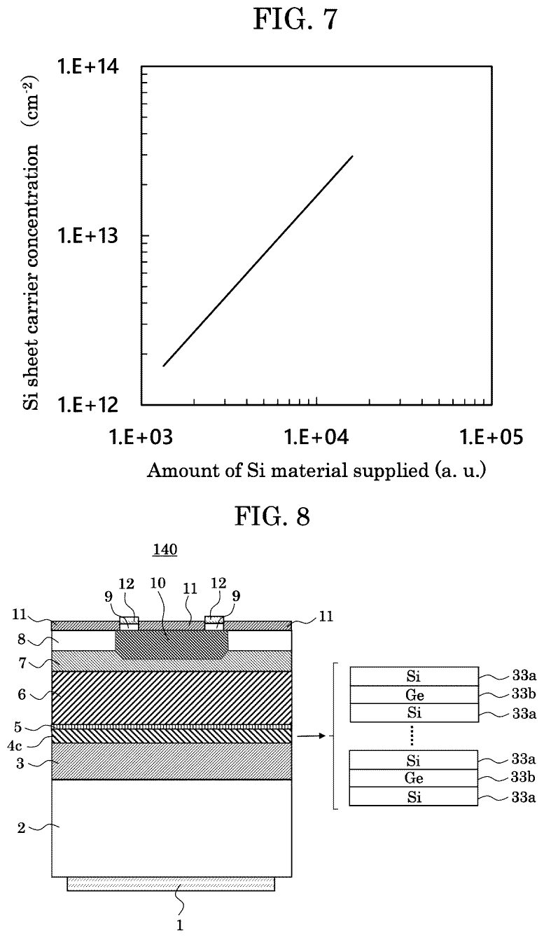

As an example, FIG. 7 shows the relationship between the Si sheet carrier concentration and the amount of Si material supplied. By controlling the crystal growth temperature and the amount of semiconductor material supplied in such a way, it is possible to form a structure in which a semiconductor layer consisting of Si and other elements is stacked instead of a Si layer stacked at the atomic layer level. Therefore, the same effect as in Embodiment 1 can be obtained.

In Embodiment 4, silane (SiH₄) is used as a Si material. However, any material containing Si can be used as a material for crystal growth regardless of solid, liquid or gas. In Embodiment 4, arsine (AsH₃) is used as a group V atomic material, but even solid or liquid materials can be used as a material for crystal growth if the materials contain As. Furthermore, if a compound with Si can be formed using source materials containing group V atomic materials such as P or Sb other than As, a similar effect can be obtained. The crystal growth method is not only the MOVPE method but also the MBE method.

### Effects of Embodiment 4

As described above, in the semiconductor light-receiving device and the method for manufacturing the semiconductor light-receiving device according to Embodiment 4, the SiAs—AlAs digital alloy-type multiplication layer having a digital alloy structure comprising alternately stacked multiple layers of a plurality of SiAs layers and a plurality of AlAs layers is provided as the multiplication layer, thus providing an effect that a semiconductor light-receiving device having low noise and excellent reliability can be obtained and such a semiconductor light-receiving device can be easily manufactured.

### Embodiment 5

### Device Structure of Semiconductor Light-Receiving Device According to Embodiment 5

FIG. 8 is a cross-sectional view showing a device structure of a semiconductor light-receiving device 140 according to Embodiment 5. An example of the semiconductor light-receiving device 140 according to Embodiment 5 is an SACM-type APD.

The semiconductor light-receiving device 140 according to Embodiment 5 includes: an n-type AlInAs buffer layer 3 having a carrier concentration of 1×10¹⁸ to 5×10¹⁸ cm⁻³ and a thickness of 0.1 to 0.5 μm; an i-type Si—Ge digital alloy-type multiplication layer 4c that has a thickness of 0.05 to 0.2 μm and has a digital alloy structure comprising alternately stacked multiple layers of a plurality of i-type Si layers (for example, a thickness of two MLs) and a plurality of i-type Ge layers (for example, a thickness of two MLS); a p-type AlInAs electric field control layer 5 having a carrier concentration of 0.5×10¹⁸ to 1×10¹⁸ cm⁻³ and a thickness of 0.05 to 0.15 μm; an n-type InGaAs light absorption layer 6 having a carrier concentration of 1×10¹⁵ to 5×10¹⁵ cm⁻³ and a thickness of 1.0 to 1.5 μm; an i-type AlInAs window layer 7 having a thickness of 0.05 to 1 μm; an n-type InP window layer 8 having a carrier concentration of 0.1×10¹⁵ to 5×10¹⁵ cm⁻³ and a thickness of 0.5 to 1.0 μm; and a p-type InGaAs contact layer 9 with a circular shape having a carrier concentration of 1×10¹⁸ to 5×10¹⁸ cm⁻³ and a thickness of 0.1 to 0.5 μm, which are sequentially formed above an n-type InP substrate 2.

The semiconductor light-receiving device 140 according to Embodiment 5 further includes: a Zn 10 (p-type conductive selective diffusion region region) provided in the n-type InP window layer 8 and a part of the i-type AlInAs window layer 7; a SiNx surface protection film 11 provided on the surface of the n-type InP window layer 8 including the surface of the Zn selective diffusion region 10; an n-type electrode 1 provided on the back side of the n-type InP substrate 2; and a p-type electrode 12 provided on the surface of the p-type InGaAs contact layer 9 with the circular shape.

The semiconductor light-receiving device 140 according to Embodiment 5 is characterized in that the multiplication layer is composed of the i-type Si—Ge digital alloy-type multiplication layer 4c that has the digital alloy structure comprising alternately stacked multiple layers of the plurality of i-type Si layers and the plurality of i-type Ge layers.

The i-type Si layer described above refers to a Si superlattice layer having a thickness N times (1≤N≤20) a thickness of a Si monolayer. The i-type Ge layer described above refers to a Ge superlattice layer having a thickness M times (1≤M≤20) a thickness of a Ge monolayer. The i-type Si layer is also referred to as a first group IV atomic superlattice layer 33a, the i-type AlAs layer is also referred to as a second group IV atomic superlattice layer 33b, and the i-type Si—Ge digital alloy-type multiplication layer 4c is simply referred to as the digital alloy-type multiplication layer.

In the description above, as an example of the i-type Si—Ge digital alloy-type multiplication layer 4c, a multiplication layer in which a plurality of i-type Si layers each having a thickness of two monolayers (MLs) and a plurality of i-type Ge layers each having a thickness of two MLs are alternately stacked a plurality of times is given. However, the i-type Si layer may have a thickness within a range of N times (1≤N≤20) the thickness of the monolayer, and the i-type Ge layer may have a thickness within a range of M times (1≤M≤20) the thickness of the monolayer. More preferably, the i-type Si layer may have a thickness within a range of N times (1≤N≤6) the thickness of the monolayer, and the i-type Ge layer may have a thickness within a range of M times (1≤M≤6) the thickness of the monolayer. For the i-type Si—Ge digital alloy-type multiplication layer 4c, when the i-type Si layer and the i-type Ge layer are alternately stacked a plurality of times, the number of stacking layers is preferably in the range of 5 to 300.

### Method for Manufacturing Semiconductor Light-Receiving Device According to Embodiment 5

The semiconductor light-receiving device 140 according to Embodiment 5 can be manufactured by forming each semiconductor layer above the InP substrate using the MOVPE method. A method for manufacturing an SACM-type APD which is an example of the semiconductor light-receiving device 140 according to Embodiment 5 will be described below.

The n-type AlInAs buffer layer 3, the i-type SiAs—AlAs digital alloy-type multiplication layer 4c that has the digital alloy structure comprising alternately stacked multiple layers of the plurality of i-type Si layers (a thickness of two MLs) and a plurality of i-type Ge layers (a thickness of two MLs), the p-type AlInAs electric field control layer 5, the n-type InGaAs light absorption layer 6, the i-type AlInAs window layer 7, the n-type InP window layer 8, and the p-type InGaAs contact layer 9 are sequentially grown on the surface of the n-type InP substrate 2 by the MOVPE method at the crystal growth temperature of 550° C.

When growing the i-type Si layer using the MOVPE method, silane (SiH₄), which is the silicon source, is used as a source gas. When growing the i-type Ge layer using the MOVPE method, germane (GeH₄), which is a germanium source, is used as a source gas.

When the MOVPE method is used as the epitaxial crystal growth method, the crystal growth temperature is preferably around 550° C., but may also be within the temperature range from 500° C. to 600° C.

Since the wafer process after the epitaxial crystal growth is the same as in Embodiment 1, a detailed description is omitted.

### Action of Semiconductor Light-Receiving Device According to Embodiment 5

In addition to the combination of Si and group V atomic materials shown in Embodiment 1, a same effect can be expected when the group V atomic material is replaced with Ge or carbon (C), which is a group IV atomic material. Since Ge or C is a group IV atomic material like Si, the effect of partially improving the interface control during crystal growth can also be expected. In addition, if Ge or C is used, the bandgap value can be changed more than that of the Si material described above, so that the energy barrier to electrons in the conduction band can be controlled as described in Embodiment 3.

### Effects of Semiconductor Light-Receiving Device According to Embodiment 5

As described above, in the semiconductor light-receiving device according to Embodiment 5, the Si—Ge digital alloy-type multiplication layer that has a digital alloy structure comprising alternately stacked multiple layers of a plurality of Si layers and a plurality of Ge layers is provided as a multiplication layer, the energy barrier when carriers conduct from the absorption layer to the multiplication layer containing Si is reduced, thus providing an effect of obtaining a semiconductor light-receiving device capable of high-speed operation.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 n-type electrode
2 n-type InP substrate
3 n-type AlInAs buffer layer
4 i-type Si—AlAs digital alloy-type multiplication layer
4a i-type Si—AlAs digital alloy-type multiplication layer
4b i-type SiAs—AlAs digital alloy-type multiplication layer
4c i-type Si—Ge digital alloy-type multiplication layer
5 p-type AlInAs electric field control layer
6 n-type InGaAs light absorption layer
7 i-type AlInAs window layer
8 n-type InP window layer
9 p-type InGaAs contact layer
10 Zn selective diffusion region
12 p-type electrode
22 i-type AlₓGa_{y}In_{1-x-y}As transition layer
30a, 31a, 32a first semiconductor layer
30b, 31b, 32b second semiconductor layer
33a first group IV atomic superlattice layer
33b second group IV atomic superlattice layer 100, 110, 120, 130, 140 semiconductor light-receiving device

1. A semiconductor light-receiving device comprising:
a semiconductor substrate;
a digital alloy-type multiplication layer formed above the semiconductor substrate and having a digital alloy structure, the digital alloy structure comprising alternately stacked multiple layers of a plurality of first semiconductor layers and a plurality of second semiconductor layers, the first semiconductor layer comprising a Si layer and having a thickness N times (1≤N≤20) a thickness of a Si monolayer, the second semiconductor layer having a bandgap energy larger than a bandgap energy of the first semiconductor layer and having a thickness M times (1≤M≤20) a thickness of a monolayer;
an electric field control layer formed above the digital alloy-type multiplication layer and configured to relax an electric field; and
a light absorption layer formed above the electric field control layer and configured to absorb incident light.

2. (canceled)

3. The semiconductor light-receiving device according to claim 1, wherein
the thickness of the second semiconductor layer is larger than the thickness of the first semiconductor layer.

4. (canceled)

5. The semiconductor light-receiving device according to claim 1, wherein
the second semiconductor layer is made of a group III-V compound semiconductor.

6. (canceled)

7. The semiconductor light-receiving device according to claim 1, wherein
a transition layer to be configured to relax a strain is provided between the digital alloy-type multiplication layer and the electric field control layer.

8. A method for manufacturing a semiconductor light-receiving device comprising:
a step of sequentially epitaxially crystal-growing above an n-type InP substrate, by an MOVPE method, an n-type AlInAs buffer layer, a digital alloy-type multiplication layer having a digital alloy structure comprising alternately stacked multiple layers of a plurality of Si layers or Si-containing layers with each thickness of N times (1≤N≤20) a thickness of a monolayer and a plurality of AlAs layers with each thickness of M times (1≤M≤20) a thickness of a monolayer, a p-type AlInAs electric field control layer, an n-type InGaAs light absorption layer, an i-type AlInAs window layer, an n-type InP window layer, and a p-type InGaAs contact layer; and
a step of forming a Zn selective diffusion region in the n-type InP window layer and a part of the i-type AlInAs window layer.

9. The method for manufacturing a semiconductor light-receiving device according to claim 8, wherein
the crystal growth temperature by the MOVPE method is within a range of 500° C. to 600° C.

10. The method for manufacturing a semiconductor light-receiving device according to claim 8, wherein
silane is used as a source gas of Si during crystal growth of the Si layers or the Si-containing layers by the MOVPE method.

11. A semiconductor light-receiving device comprising:
a semiconductor substrate;
a digital alloy-type multiplication layer formed above the semiconductor substrate and having a digital alloy structure, the digital alloy structure comprising alternately stacked multiple layers of a plurality of first Si-containing semiconductor layers and a plurality of second semiconductor layers, the first Si-containing semiconductor layer being made of Si and group V atoms and having a thickness N times (1≤N≤20) a thickness of a monolayer, the second semiconductor layer being made of a group III-V compound semiconductor that has a bandgap energy larger than a bandgap energy of the first semiconductor layer and has a thickness M times (1≤M≤20) a thickness of a monolayer;
an electric field control layer formed above the digital alloy-type multiplication layer and configured to relax an electric field; and
a light absorption layer formed above the electric field control layer and configured to absorb incident light.

12. The semiconductor light-receiving device according to claim 11, wherein
a transition layer to be configured to relax a strain is provided between the digital alloy-type multiplication layer and the electric field control layer.
